(19) United States
(12) Patent Application Publication
(10) Pub. No.: US 2024/0304665 A1
(43) Pub. Date: Sep. 12, 2024

(54) SWITCHING DEVICE AND METHOD FOR MANUFACTURING THE SAME

(71) Applicant: DENSO CORPORATION, Kariya-city (JP)

(72) Inventor: MASAKAZU WATANABE, Kariya-city (JP)

(21) Appl. No.: 18/669,766

(22) Filed: May 21, 2024

Related U.S. Application Data
(63) Continuation of application No. PCT/JP2022/041516, filed on Nov. 8, 2022.

(30) Foreign Application Priority Data
Feb. 4, 2022 (JP) 2022-016677

(51) Int. Cl. H01L 29/06; H01L 21/266; H01L 29/10; H01L 29/423; H01L 29/66; H01L 29/78

(52) U.S. Cl. CPC H01L 29/0623; H01L 21/266; H01L 29/1095; H01L 29/42376; H01L 29/66734; H01L 29/7813

(57) ABSTRACT

A method for manufacturing a switching device includes: forming a source region and a body region in a semiconductor substrate having a drift region; forming a mask having an opening on an upper surface of the semiconductor substrate having the drift region; after the forming of the mask, forming an electric field relaxation region in the drift region by implanting a p-type impurity into the semiconductor substrate through the opening; after the forming of the electric field relaxation region, forming a gate trench by etching the upper surface of the semiconductor substrate within the opening of the mask so that the electric field relaxation region remains below the gate trench; and after the forming of the gate trench, forming a gate insulating film and a gate electrode in the gate trench.

### CROSS REFERENCE TO RELATED APPLICATIONS

The present application is a continuation application of International Patent Application No. PCT/JP2022/041516 filed on Nov. 8, 2022, which designated the U.S. and claims the benefit of priority from Japanese Patent Application No. 2022-016677 filed on Feb. 4, 2022. The entire disclosures of all of the above applications are incorporated herein by reference.

### TECHNICAL FIELD

The present disclosure relates to a switching device and a method for manufacturing the same.

### BACKGROUND

In a switching device having a trench-type gate electrode, for example, it has been known to have a p-type electric field relaxation region at a position adjoining to a bottom surface of a gate trench. The electric field relaxation region is surrounded by an n-type drift region, and suppresses electric field concentration near a bottom end of the gate trench.

### SUMMARY

The present disclosure provides a switching device and a method for manufacturing the switching device. In an aspect, a switching device includes an electric field relaxation region in contact with a gate trench in a drift region. In an aspect, a method for manufacturing the switching device includes: forming a source region and a body region in a semiconductor substrate having the drift region; forming a mask having an opening on an upper surface of the semiconductor substrate having the drift region; after the forming of the mask, forming the electric field relaxation region in the drift region by implanting a p-type impurity into the semiconductor substrate through the opening; after the forming of the electric field relaxation region, forming the gate trench by etching the upper surface of the semiconductor substrate within the opening of the mask so that the electric field relaxation region remains below the gate trench; and after the forming of the gate trench, forming a gate insulating film and a gate electrode in the gate trench.

### BRIEF DESCRIPTION OF THE DRAWINGS

Features and advantages of the present disclosure will become more apparent from the following detailed description made with reference to the accompanying drawings, in which:

FIG. 1 is a cross-sectional view of a MOSFET according to an embodiment;

FIG. 2 is a diagram for explaining a method for manufacturing the MOSFET according to the embodiment;

FIG. 3 is a diagram for explaining the method for manufacturing the MOSFET according to the embodiment;

FIG. 4 is a diagram for explaining the method for manufacturing the MOSFET according to the embodiment;

FIG. 5 is a diagram for explaining the method for manufacturing the MOSFET according to the embodiment;

FIG. 6 is a diagram for explaining the method for manufacturing the MOSFET according to the embodiment;

FIG. 7 is a diagram for explaining the method for manufacturing the MOSFET according to the embodiment;

FIG. 8 is a diagram for explaining the method for manufacturing the MOSFET according to the embodiment;

FIG. 9 is a diagram for explaining a current path in the MOSFET according to the embodiment;

FIG. 10 is a diagram for explaining a current path in a MOSFET of a comparative example;

FIG. 11 is a cross-sectional view of a MOSFET of a modified embodiment;

FIG. 12 is a cross-sectional view showing a lateral misalignment of an electric field relaxation region with respect to a gate trench; and

FIG. 13 is a cross-sectional view showing a variation in vertical position of electric field relaxation regions when p-type impurities are implanted to bottoms of the gate trenches.

### DETAILED DESCRIPTION

To begin with, relevant technologies will be described only for understanding the embodiments of the present disclosure.

For example, in a switching device having a trench-gate electrode, a p-type electric field relaxation region is formed at a position adjoining to a bottom surface of a gate trench. The electric field relaxation region is surrounded by an n-type drift region, and suppresses electric field concentration near a bottom end of the gate trench.

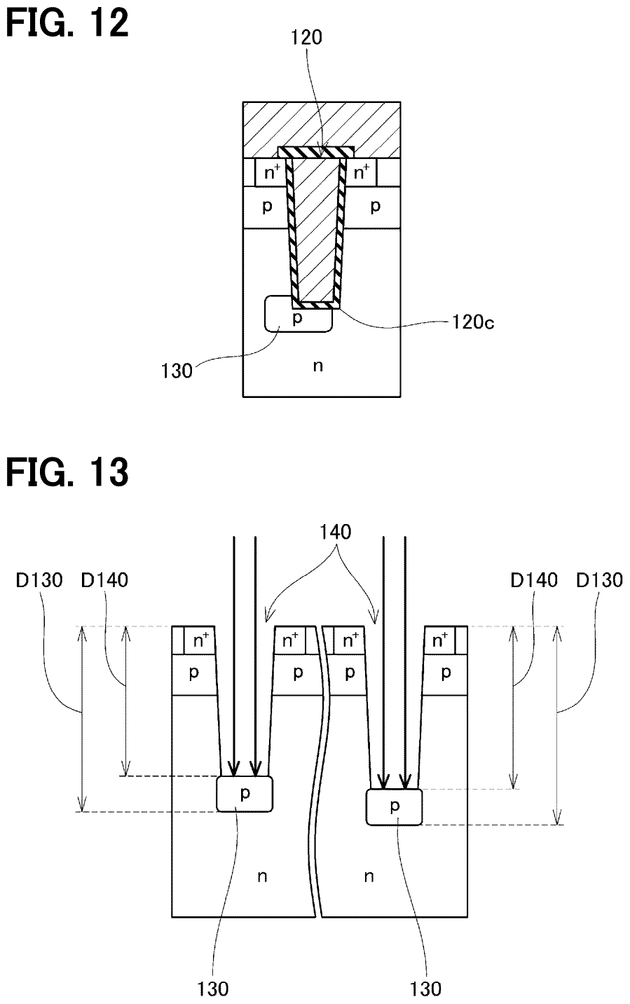

In a method for manufacturing such a switching device, for example, a p-type impurity is implanted into a part of the drift region to form the electric field relaxation region. After forming the electric field relaxation region, an n-type layer and a p-type layer are sequentially epitaxially grown on the semiconductor substrate. Next, a gate trench is formed in an upper surface of the semiconductor substrate. For example, the gate trench is formed such that the bottom end of the gate trench is located within the electric field relaxation region. Thereafter, a gate electrode is formed in the gate trench. In such a manufacturing method, it is necessary to form the gate trench in alignment with the electric field relaxation region so that the bottom surface of the gate trench is located within the electric field relaxation region. However, if the alignment accuracy of photolithography is not so high, the gate trench may be displaced in a lateral direction with respect to the electric field relaxation region. For example, as shown in FIG. 12, if a gate trench 120 is misaligned with respect to an electric field relaxation region 130 in the lateral direction, a corner portion 120c at the bottom end of the gate trench 120 may protrude outside of the electric field relaxation region 130. When the corner portion 120c of the gate trench 120 protrudes from the electric field relaxation region 130 in this manner, the electric field is likely to concentrate in the vicinity of the corner portion 120c, and the breakdown voltage of the switching device decreases. For this reason, in the manufacturing method of the relevant technology, it is conceivable to increase the width of the electric field relaxation region to be significantly larger than the width of the gate trench so that the bottom surface of the gate trench is located within the electric field relaxation region even if the gate trench is misaligned with respect to the electric field relaxation region. However, increasing the width of the electric field relaxation region causes an increase in the on-resistance of the switching device and an increase in the size of the switching device.

As another relevant technology, there is a manufacturing method in which a gate trench is formed before an electric field relaxation region is formed, and a p-type impurity is implanted to the bottom of the gate trench to form the electric field relaxation region. However, such a manufacturing method causes a problem that a vertical position of the bottom end of the electric field relaxation region (that is, the position in the thickness direction of the semiconductor substrate) is likely to vary. That is, when forming the gate trench in the upper surface of a semiconductor substrate, the depth of the gate trench is likely to be largely varied. Therefore, when the electric field relaxation region is formed by implanting a p-type impurity to the bottom surface of the gate trench, the position of the bottom end of the electric field relaxation region is likely to vary largely in the vertical direction. For example, as shown in FIG. 13, in a case where there is a variation in depth D140 of gate trenches 140, if electric field relaxation regions 130 are formed by implanting a p-type impurity to the bottom surfaces of the gate trenches 140, the position D130 of the bottom ends of the electric field relaxation regions 130 is likely to vary due to the influence of the variation in the depth D140 of the gate trenches 140. The variation in position of the bottom ends of the electric field relaxation regions in the vertical direction causes a variation in characteristics of the switching device.

The present disclosure proposes a technique that is capable of forming an electric field relaxation region with high positional accuracy.

The present disclosure provides a method for manufacturing a switching device. In an embodiment of the present disclosure, a method is for manufacturing a switching device that includes a semiconductor substrate having a gate trench in an upper surface thereof, a gate electrode disposed in the gate trench and insulated from the semiconductor substrate by a gate insulating film, an n-type source region in contact with the gate insulating film at a side surface of the gate trench, a p-type body region in contact with the gate insulating film at the side surface of the gate trench below the source region, a p-type electric field relaxation region in contact with the gate insulating film at a bottom surface of the gate trench, and an n-type drift region in contact with the gate insulating film at the side surface of the gate trench below the body region and in contact with a side surface and a bottom surface of the electric field relaxation region. In an embodiment, the method for manufacturing the switching device includes: forming the source region and the body region in the semiconductor substrate having the drift region; forming a mask defining an opening on the upper surface of the semiconductor substrate having the drift region; after the forming of the mask, forming the electric field relaxation region in the drift region by implanting a p-type impurity to the semiconductor substrate through the opening; after the forming of the electric field relaxation region, forming the gate trench by etching the upper surface of the semiconductor substrate within the opening while remaining the electric field relaxation region below the gate trench; and after the forming of the gate trench, forming the gate insulating film and the gate electrode.

Note that the forming of the source region and the body region may be performed at any time. For example, the forming of the source region and the body region may be performed before the forming of the mask, or after the forming of the gate electrode.

In the method described above, the electric field relaxation region is formed by implanting the p-type impurity into the semiconductor substrate through the opening of the mask, and then the gate trench is formed by etching the upper surface of the semiconductor substrate within the opening of the same mask. Therefore, it is possible to suppress misalignment in a lateral direction between the electric field relaxation region and the gate trench. Further, in the method described above, since the gate trench is formed after the forming of the electric field relaxation region, the position of the bottom end of the electric field relaxation region is not affected by the variation in the depth of the gate trench. Therefore, the variation in the position of the bottom end of the electric field relaxation region in the vertical direction is suppressed. In this way, according to the method described above, it is possible to suppress the displacement of the electric field relaxation region in the lateral direction with respect to the gate trench, as well as to suppress the variation in the position of the bottom end of the electric field relaxation region in the vertical direction. That is, the electric field relaxation region can be formed with high positional accuracy.

According to an embodiment of the manufacturing method of the present disclosure, in the forming of the electric field relaxation region, the electric field relaxation region may be formed so that the width of the electric field relaxation region increases toward the bottom end.

According to such a configuration, the width of the electric field relaxation region becomes large near the bottom surface of the gate trench, so the bottom surface of the gate trench is likely to be entirely covered with the electric field relaxation region, and electric field concentration near the bottom end of the gate trench can be effectively suppressed.

According to an embodiment of the manufacturing method of the present disclosure, in the forming of the gate trench, the gate trench may be formed such that the width of the gate trench becomes narrower toward the bottom end.

According to such a configuration, the width of the bottom surface of the gate trench is narrow, so the bottom surface of the gate trench is likely to be entirely covered with the electric field relaxation region, and electric field concentration near the bottom end of the gate trench can be effectively suppressed.

According to an embodiment, the manufacturing method of the present disclosure may further include etching the side surface of the gate trench, after the forming of the gate trench.

According to such a configuration, the width of the portion where the drift region contacts the gate insulating film above the electric field relaxation region is increased. Therefore, a variation in mirror capacitance of the switching element is suppressed.

According to an embodiment of the manufacturing method of the present disclosure, the width of the bottom surface of the gate trench may be smaller than the width of the electric field relaxation region. In the forming of the gate trench, the gate trench may be formed such that the electric field relaxation region is in contact with each corner portion of the gate trench defined between the bottom surface of the gate trench and the side surface of the gate trench.

According to such a configuration, electric field concentration near the bottom end of the gate trench can be effectively suppressed.

According to an embodiment of the manufacturing method of the present disclosure, the drift region may have a low concentration region and a high concentration region having an n-type impurity concentration higher than the low concentration region and disposed above the low concentration region. In the forming of the electric field relaxation region, the electric field relaxation region may be formed in the high concentration region such that the bottom end of the electric field relaxation region is located within the high concentration region.

According to such a configuration, since the position of the bottom end of the electric field relaxation region does not easily vary in the depth direction, it is easy to position the bottom end of the electric field relaxation region above the bottom end of the high concentration region. By positioning the bottom end of the electric field relaxation region above the bottom end of the high concentration region, the on-resistance of the switching element can be reduced.

The present disclosure also provides a switching device. According to an embodiment, a switching device may include: a semiconductor substrate having a plurality of gate trenches in an upper surface thereof; a plurality of gate electrodes disposed in the gate trenches and insulated from the semiconductor substrate by gate insulating films; a plurality of n-type source regions in contact with the gate insulating films at side surfaces of the gate trenches; a p-type body region in contact with the gate insulating films at the side surfaces of the gate trenches below the source regions; a plurality of p-type electric field relaxation regions in contact with the gate insulating films at bottom surfaces of the gate trenches; and an n-type drift region in contact with the gate insulating films at the side surfaces of the gate trenches below the body region and in contact with side surfaces and bottom surfaces of the electric field relaxation regions. In each of the plurality of gate trenches, a deviation between a center in the width direction of the gate trench and a center in the width direction of the electric field relaxation region below the gate trench may be 0.1 μm or less. Among the plurality of electric field relaxation regions, a variation in distance in a thickness direction of the semiconductor substrate from the upper surface of the semiconductor substrate to a bottom end of the electric field relaxation region may be ±2% or less.

In such a switching device, since the deviation in the lateral direction between the gate trench and the electric field relaxation region is small, the electric field concentration can be suitably suppressed near the bottom end of the gate trench. Further, in such a switching device, the variation in the position of the bottom ends of the electric field relaxation regions in the depth direction (that is, in the thickness direction of the semiconductor substrate) are small. Therefore, the variation in characteristics is less likely to occur in such a switching device. Further, a switching device with such high positional accuracy of the electric field relaxation region can be manufactured by any of the manufacturing methods described above.

According to an embodiment of the switching device of the present disclosure, in each of the plurality of gate trenches, the width of the bottom surface of the gate trench may be smaller than the width of the corresponding electric field relaxation region disposed below the gate trench. In each of the plurality of gate trenches, the electric field relaxation region may be in contact with each corner portion defined between the bottom surface of the gate trench and the side surface of the gate trench.

According to such a configuration, the electric field concentration near the bottom end of the gate trench can be effectively suppressed.

Hereinafter, embodiments of the present disclosure will be further described with reference to the drawings.

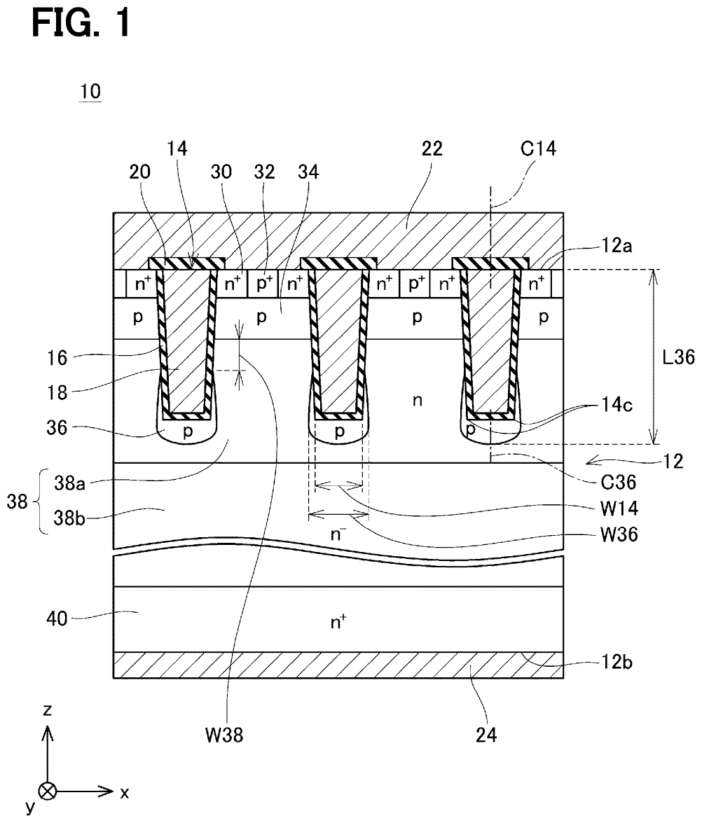

FIG. 1 shows a metal oxide semiconductor field effect transistor (MOSFET) 10 according to an embodiment. The MOSFET 10 has a semiconductor substrate 12. The semiconductor substrate 12 is made of silicon carbide (SiC). Alternatively, the semiconductor substrate 12 may be made of other materials such as silicon. Note that hereinafter, a thickness direction of the semiconductor substrate 12 is referred to as a z direction, a direction parallel to an upper surface 12a of the semiconductor substrate 12 is referred to as an x direction, and a direction parallel to the upper surface 12a of the semiconductor substrate 12 and orthogonal to the x direction is referred to as a y direction.

A plurality of gate trenches 14 are provided in the upper surface 12a of the semiconductor substrate 12. The gate trenches 14 are arranged at intervals in the x direction. Each gate trench 14 extends long in the y direction. The inner surface of each gate trench 14 is covered with a gate insulating film 16. A gate electrode 18 is arranged in each gate trench 14. Each gate electrode 18 is insulated from the semiconductor substrate 12 by the gate insulating film 16. An upper surface of each gate electrode 18 is covered with an interlayer insulating film 20.

The MOSFET 10 has a source electrode 22 and a drain electrode 24. The source electrode 22 covers the upper surface 12a of the semiconductor substrate 12 and the interlayer insulating film 20. The source electrode 22 is in contact with the semiconductor substrate 12 at the upper surface 12a. The source electrode 22 is insulated from the gate electrodes 18 by the interlayer insulating film 20. The drain electrode 24 covers the entirety of the lower surface 12b of the semiconductor substrate 12.

The semiconductor substrate 12 has a plurality of source regions 30, a plurality of contact regions 32, a body region 34, a plurality of electric field relaxation regions 36, a drift region 38, and a drain region 40.

Each of the source regions 30 is an n-type region having a high n-type impurity concentration. The source region 30 is disposed in a range facing the upper surface 12a of the semiconductor substrate 12. The source region 30 is in ohmic contact with the source electrode 22. The source region 30 is in contact with the gate insulating film 16 at the upper end of the side surface of the gate trench 14.

Each of the contact regions 32 is a p-type region having a high p-type impurity concentration. The contact region 32 is disposed in a range interposed between the source regions 30 and facing the upper surface 12a of the semiconductor substrate 12. The contact region 32 is in ohmic contact with a source electrode 22.

The body region 34 is a p-type region having a p-type impurity concentration lower than that of the contact region 32. The body region 34 is disposed below the plurality of source regions 30 and the plurality of contact regions 32. The body region 34 is in contact with the respective source regions 30 and the respective contact regions 32 below the source regions 30 and the contact regions 32. The body region 34 is in contact with the gate insulating films 16 at the side surfaces of the gate trenches 14 below the respective source regions 30.

Each of the electric field relaxation regions 36 is a p-type region having a p-type impurity concentration lower than that of the contact region 32. The electric field relaxation region 36 is arranged below the corresponding gate trench 14. The electric field relaxation region 36 extends long in the y direction along the bottom surface of the corresponding gate trench 14. The electric field relaxation region 36 is in contact with the gate insulating film 16 over the entire bottom surface of the corresponding gate trench 14. Note that each electric field relaxation region 36 is connected to the body region 34 by a p-type region provided at a position not shown. However, in some embodiments, the electric field relaxation regions 36 may not be connected to the body region 34 and may be floating with respect to the body region 34.

The drift region 38 is an n-type region having a relatively low n-type impurity concentration. The drift region 38 is disposed below the body region 34. The drift region 38 is in contact with the gate insulating film 16 at a side surface of each gate trench 14 below the body region 34. The drift region 38 is in contact with the side and bottom surfaces of each electric field relaxation region 36. The drift region 38 includes a high concentration region 38a and a low concentration region 38b. The high concentration region 38a has an n-type impurity concentration lower than that of the source region 30. The low concentration region 38b has an n-type impurity concentration lower than that of the high concentration region 38a.

The high concentration region 38a is distributed from the position of the lower surface of the body region 34 to a position below the bottom end of each electric field relaxation region 36. The high concentration region 38a is in contact with the body region 34 on the bottom side of the body region 34. The high concentration region 38a is in contact with the gate insulating film 16 at the side surface of each gate trench 14 below the body region 34. That is, the high concentration region 38a is in contact with the gate insulating film 16 at the side surface of each gate trench 14 in a range between the electric field relaxation region 36 and the body region 34 (that is, the range of the width W38 shown in FIG. 1). The high concentration region 38a is in contact with the side and bottom surfaces of each electric field relaxation region 36. That is, the bottom end of each electric field relaxation region 36 is located within the high concentration region 38a.

The low concentration region 38b is disposed below the high concentration region 38a. The low concentration region 38b is in contact with the high concentration region 38a on the bottom side of the high concentration region 38a. The low concentration region 38b is separated from the electric field relaxation regions 36 by the high concentration region 38a. That is, the low concentration region 38b is not in contact with the electric field relaxation regions 36.

The drain region 40 is an n-type region having an n-type impurity concentration higher than that of the drift region 38 (that is, having the n-type impurity concentration higher than the n-type impurity concentrations of both the high concentration region 38a and the low concentration region 38b). The drain region 40 is disposed below the low concentration region 38b. The drain region 40 is in contact with the low concentration region 38b on the bottom side of the low concentration region 38b. The drain region 40 is disposed in an area facing the lower surface 12b of the semiconductor substrate 12. The drain region 40 is in ohmic contact with the drain electrode 24.

In FIG. 1, a center C14 indicates the center of the gate trench 14 in the width direction or lateral direction (that is, in the x direction). Further, in FIG. 1, a center C36 indicates the center of the electric field relaxation region 36 in the width direction or lateral direction (that is, in the x direction). In regard to all the gate trenches 14 included in the MOSFET 10, the deviation between the center C14 of the gate trench 14 and the center C36 of the electric field relaxation region 36 in the lateral direction is 0.1 μm or less. That is, in the x direction, the center C14 of the gate trench 14 and the center C36 of the electric field relaxation region 36 substantially coincide with each other. In addition, in regard to all the gate trenches 14 included in the MOSFET 10, the width W14 of the bottom surface of the gate trench 14 is narrower than the width W36 of the electric field relaxation region 36 at the position of the bottom surface of the gate trench 14. Therefore, each corner portion 14c connecting the bottom surface of the gate trench 14 and the side surface of the gate trench 14 is covered with the electric field relaxation region 36. That is, at each corner portion 14c of the gate trench 14, the electric field relaxation region 36 is in contact with the gate insulating film 16.

In FIG. 1, a distance L36 indicates the distance in the z direction from the upper surface 12a of the semiconductor substrate 12 to the bottom end of the electric field relaxation region 36. The variation in the distance L36 is +2% or less between the plurality of electric field relaxation regions 36 included in the MOSFET 10. That is, the variation in the distance L36 is extremely small.

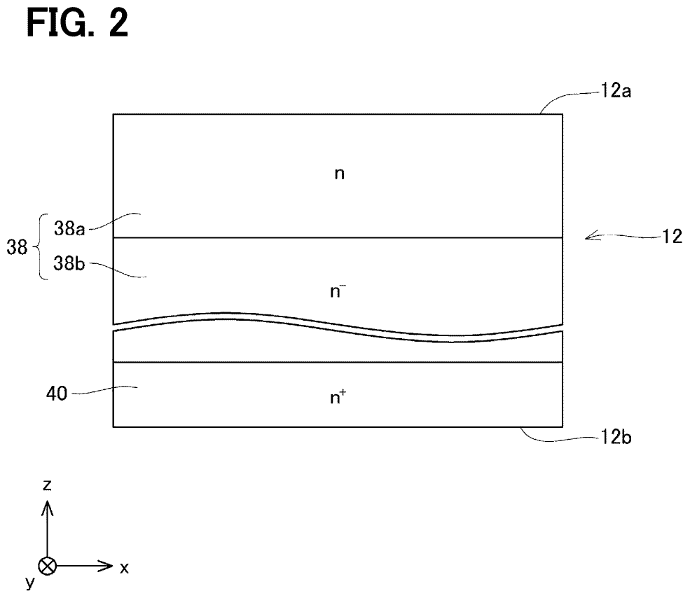

Next, a method for manufacturing the MOSFET 10 according to an embodiment will be described. First, the semiconductor substrate 12 shown in FIG. 2 (that is, the semiconductor substrate 12 before being processed) is prepared. The semiconductor substrate 12 shown in FIG. 2 is made of SiC. Alternatively, the semiconductor substrate 12 may be made of other materials such as silicon. The semiconductor substrate 12 shown in FIG. 2 has the drain region 40, the low concentration region 38b, and the high concentration region 38a. The low concentration region 38b is arranged above the drain region 40, and the high concentration region 38a is arranged above the low concentration region 38b. The low concentration region 38b and the high concentration region 38a may be formed by epitaxial growth, or may be formed by ion implantation. The semiconductor substrate 12 shown in FIG. 2 is not provided with electrodes, insulating films, or the like on the upper surface 12a and the lower surface 12b thereof.

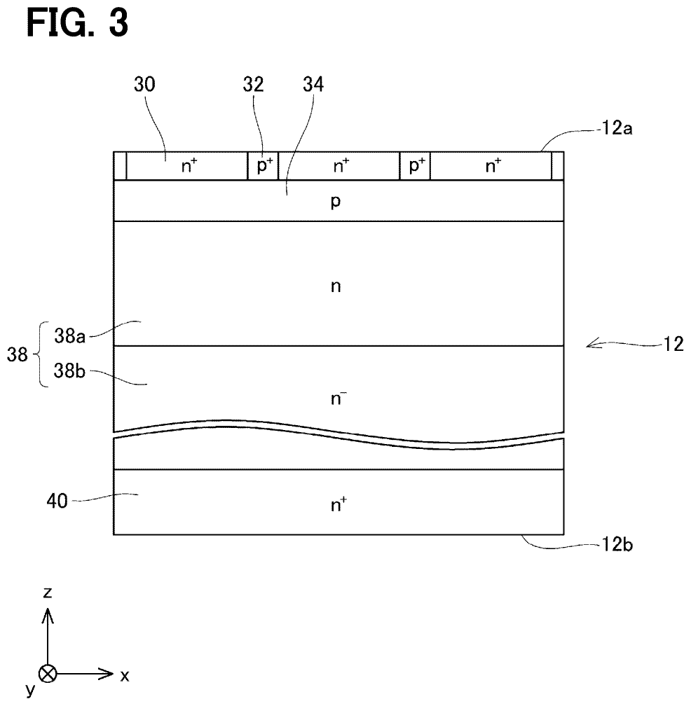

First, by performing epitaxial growth, ion implantation, or the like on the semiconductor substrate 12 of FIG. 2, a source region 30, a contact region 32, and a body region 34 are formed as shown in FIG. 3.

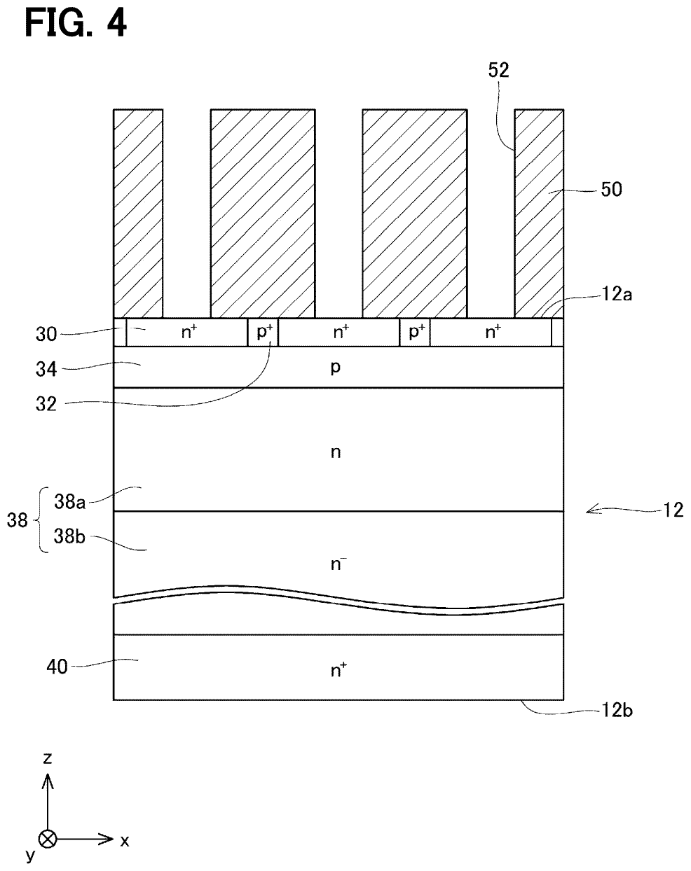

Next, as shown in FIG. 4, a mask 50 made of silicon oxide is formed on the upper surface 12a of the semiconductor substrate 12. Next, a plurality of openings 52 are formed in the mask 50 by photolithography, etching, or the like. In this case, the mask 50 is formed so that the openings 52 are positioned above the respective portions of the semiconductor substrate 12 where the gate trenches 14 and the electric field relief regions 36 are to be formed. In each opening 52, the upper surface 12a of the semiconductor substrate 12 is exposed.

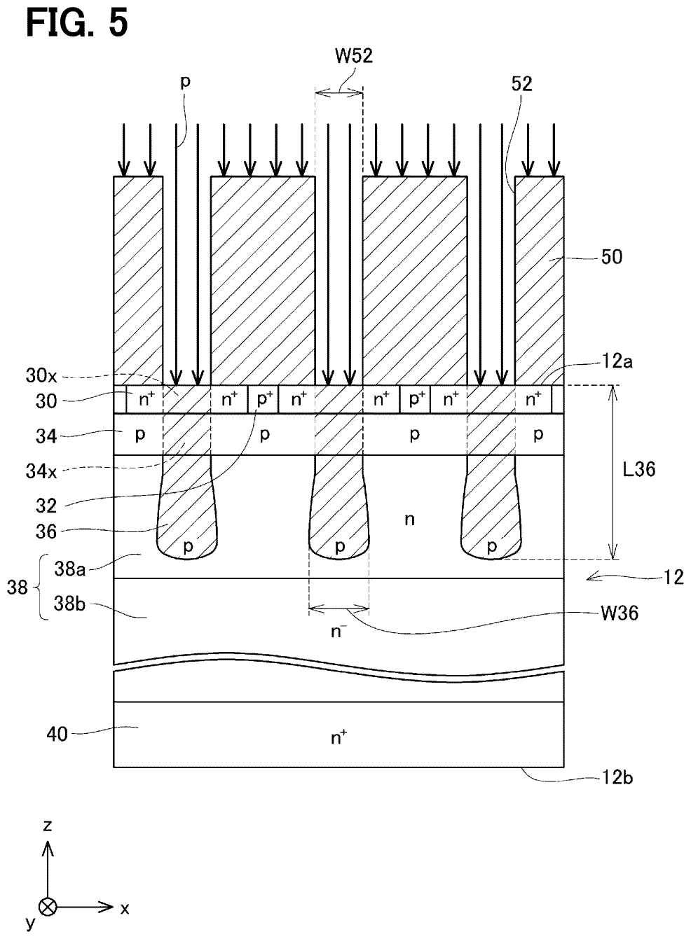

Next, as shown in FIG. 5, p-type impurity ions are implanted into the semiconductor substrate 12 through the mask 50. In the area where the mask 50 exists, the p-type impurity is blocked by the mask 50. Therefore, the p-type impurity is implanted into the semiconductor substrate 12 through the openings 52. In this case, the implantation energy of the p-type impurity is adjusted so that the implanted p-type impurity reaches the high concentration region 38a but does not reach the low concentration region 38b. That is, the p-type impurity is implanted in the shaded areas of the semiconductor substrate 12 shown in FIG. 5. In the p-type impurity implantation area in the high concentration region 38a, the p-type impurity is implanted at a concentration higher than that of the other area of the high concentration region 38a. As such, the p-type electric field relaxation region 36 is formed within the high concentration region 38a. In this way, the p-type electric field relaxation region 36 is formed below the opening 52. The electric field relaxation region 36 is formed such that the bottom end of the electric field relaxation region 36 is located within the high concentration region 38a (that is, the bottom end of the electric field relaxation region 36 does not touch the low concentration region 38b). In a p-type impurity implantation area 30x in the source region 30, the n-type impurity concentration of the source region 30 is higher than the implanted p-type impurity concentration. Therefore, the p-type impurity implantation area 30x of the source region 30 is maintained as the n-type. In a p-type impurity implantation area 34x of the body region 34, the p-type impurity concentration of the body region 34 increases.

The implantation depth of the p-type impurity can be controlled with relatively high precision. Therefore, the variation in the bottom end of the electric field relaxation region 36 in the depth direction is extremely small, among the electric field relaxation region 36. That is, the variation in the distance L36 is extremely small among the electric field relaxation regions 36. That is, according to this manufacturing method, the position of the bottom end of the electric field relaxation region 36 in the z direction can be accurately controlled.

Further, while the p-type impurity moves in the z-direction in the semiconductor substrate 12, the p-type impurity is scattered and diffused in the x-direction. Therefore, the width in the x direction of the p-type impurity implantation area (that is, the shaded area) shown in FIG. 5 increases toward the bottom side. As such, the width W36 of the lower portion of the electric field relaxation region 36 is slightly larger than the width W52 of the opening 52.

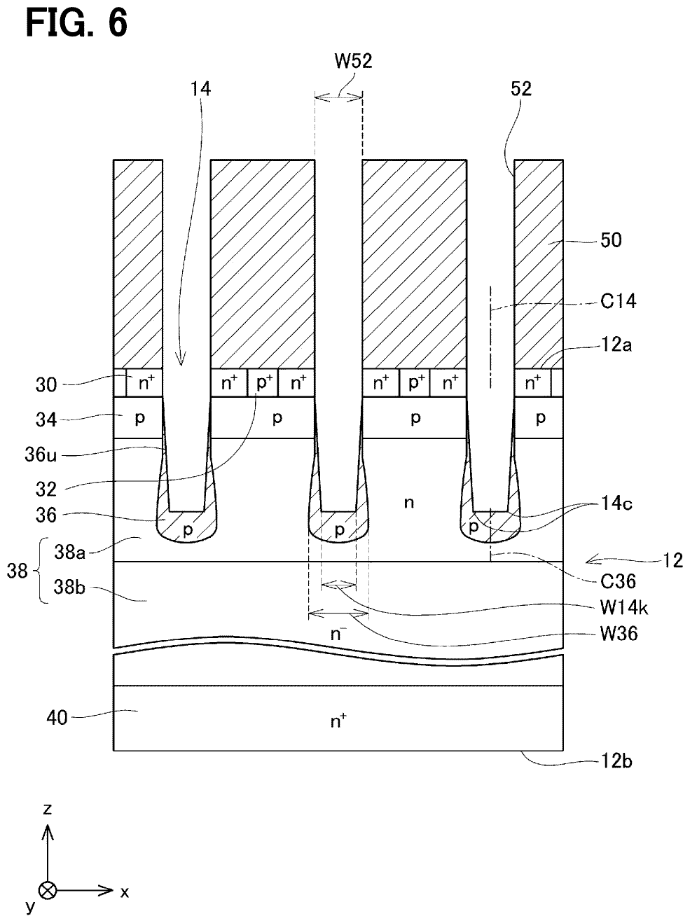

Next, the upper surface 12a of the semiconductor substrate 12 is etched using the mask 50, which has been used for the p-type impurity implantation. That is, the upper surface 12a of the semiconductor substrate 12 is etched within the opening 52 of the mask 50. As a result, the gate trench 14 is formed in the upper surface 12a of the semiconductor substrate 12, as shown in FIG. 6. In this case, the gate trench 14 is formed by etching the semiconductor substrate 12 in the z direction within the opening 52 using anisotropic etching such as reactive ion etching. The gate trench 14 is formed to penetrate the source region 30 and the body region 34 and reach the electric field relaxation region 36. In this case, the gate trench 14 is formed so that the electric field relaxation region 36 remains below the gate trench 14. By forming the gate trench 14, most parts in the p-type impurity implantation area 30x in the source region 30 and the p-type impurity implantation area 34x in the body region 34 shown in FIG. 5 are removed. Since the ion implantation shown in FIG. 5 and the etching shown in FIG. 6 are performed using the same mask 50, the gate trench 14 is formed precisely at a position overlapping the electric field relaxation region 36. Therefore, the center C14 of the gate trench 14 can be made to coincide with the center C36 of the electric field relaxation region 36 with high accuracy. That is, according to this manufacturing method, the positional deviation in the x direction between the center C14 of the gate trench 14 and the center C36 of the electric field relaxation region 36 is reduced to be 0.1 μm or less.

In the process of forming the gate trench 14, the etching condition is adjusted so that the width of the gate trench 14 in the x direction becomes narrower toward the bottom. Therefore, the width W14k of the bottom surface of the gate trench 14 in the x direction is slightly smaller than the width W52 of the opening 52. As described above, the width W36 of the bottom portion of the electric field relaxation region 36 is slightly larger than the width W52 of the opening 52. Therefore, the electric field relaxation region 36 exists on both sides of the bottom surface of the gate trench 14 in the x direction. That is, the corner portions 14c of the gate trench 14 are covered with the electric field relaxation region 36.

Next, the mask 50 is removed. Next, a carbon film is formed to cover the upper surface 12a of the semiconductor substrate 12 and the inner surface of the gate trench 14. Next, the semiconductor substrate 12 is annealed to activate the p-type impurity implanted in the semiconductor substrate 12. Note that the carbon film restricts silicon atoms from diffusing to the outside from the semiconductor substrate 12 during the annealing process. After the annealing process, the carbon film is removed.

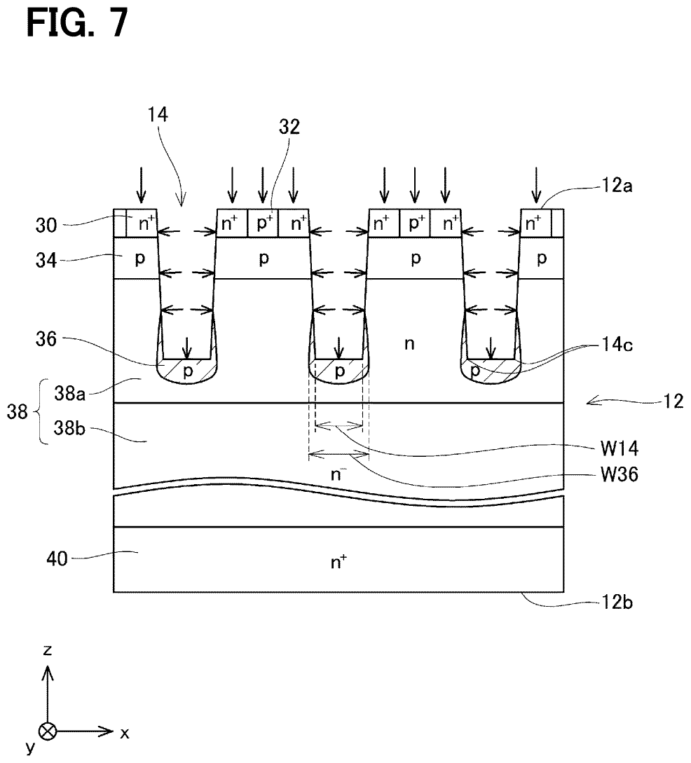

Next, as shown in FIG. 7, the upper surface 12a of the semiconductor substrate 12 and the inner surface of the gate trench 14 are etched by isotropic etching (for example, chemical dry etching (CDE)). As a result, a damaged layer existing on the upper surface 12a and the inner surface of the gate trench 14 (that is, the layer damaged by ion implantation, etching, or the like) is removed. By etching the side surface of the gate trench 14 in this manner, the width of the gate trench 14 is slightly increased. For example, the width of the bottom surface of the gate trench 14 increases from the width W14k shown in FIG. 6 to the width W14 shown in FIG. 7. Since the amount of increase in the width of the gate trench 14 is small, in the vicinity of the bottom surface of the gate trench 14, the electric field relaxation region 36 remains at positions adjacent to the side surfaces of the gate trench 14. Further, since the width of the gate trench 14 is slightly increased, the upper portions of the electric field relaxation region 36 (i.e., the portions 36u in FIG. 6) are removed. Therefore, as shown in FIG. 7, the high concentration region 38a is exposed on the side surfaces of the gate trench 14 above the electric field relaxation region 36.

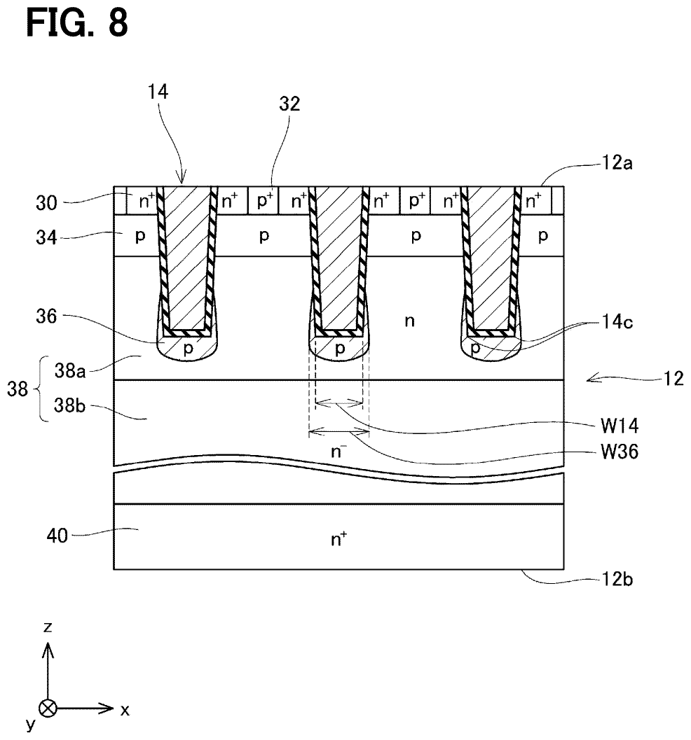

Next, as shown in FIG. 8, the gate insulating film 16 is formed so as to cover the inner surface of the gate trench 14. As a result, the source region 30 is in contact with the gate insulating film 16 at the upper end of the side surface of the gate trench 14. Further, the body region 34 is in contact with the gate insulating film 16 at the side surface of the gate trench 14 below the source region 30. The high concentration region 38a is in contact with the gate insulating film 16 below the body region 34 (that is, in the range between the body region 34 and the electric field relaxation region 36). The electric field relaxation region 36 is in contact with the gate insulating film 16 at the bottom surface of the gate trench 14 and the side surface near the bottom surface. Next, as shown in FIG. 8, the gate electrode 18 is formed inside the gate trench 14.

Thereafter, as shown in FIG. 1, the interlayer insulating film 20 is formed so as to cover the upper surface of the gate electrode 18. Next, the source electrode 22 is formed to cover the upper surface 12a of the semiconductor substrate 12 and the interlayer insulating film 20. Next, the drain electrode 24 is formed so as to cover the lower surface 12b of the semiconductor substrate 12. As a result, the MOSFET 10 shown in FIG. 1 is completed.

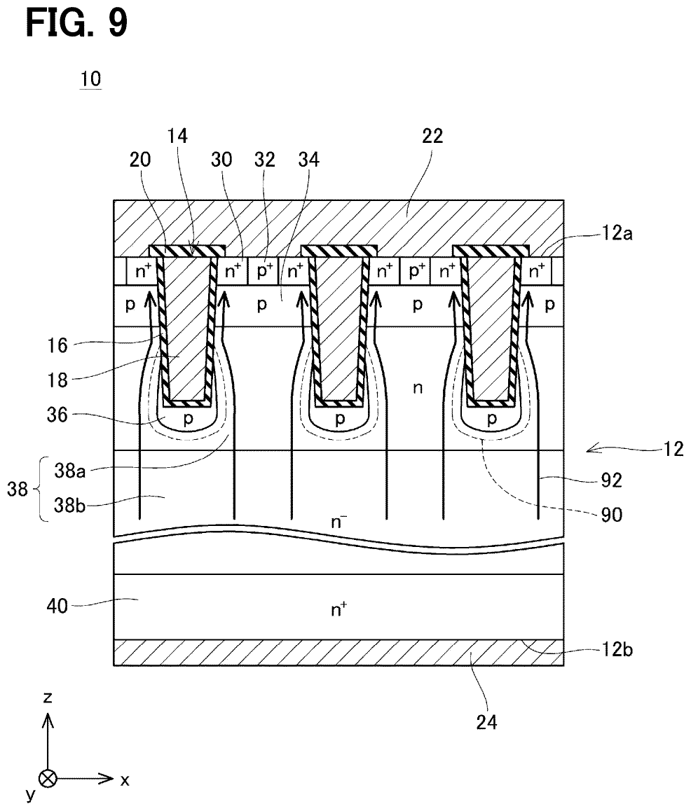

Next, an operation of MOSFET 10 will be described. The MOSFET 10 is used in a state where a higher potential is applied to the drain electrode 24 than the source electrode 22. When a potential higher than a gate threshold is applied to the gate electrode 18, a channel is formed in a portion of the body region 34 near the gate insulating film 16. As a result, as shown by an arrow 92 in FIG. 9, electrons flow from the drain region 40 to the source region 30 through the channels in the low concentration region 38b, the high concentration region 38a, and the body region 34. That is, the MOSFET 10 is turned on. When the potential of the gate electrode 18 is lowered to a potential below the gate threshold, the channels disappear and the flow of electrons stops. In other words, the MOSFET 10 is turned off.

When the MOSFET 10 is turned off, a depletion layer spreads from the body region 34 to the drift region 38. The depletion of the drift region 38 allows the MOSFET 10 to hold a high voltage applied between the drain electrode 24 and the source electrode 22. Further, when the MOSFET 10 is turned off, the depletion layer spreads from the electric field relaxation region 36 to the high concentration region 38a around the bottom end of the gate trench 14. In this way, the depletion layer spreading from the electric field relaxation region 36 to the high concentration region 38a suppresses electric field concentration around the bottom end of the gate trench 14. Therefore, the MOSFET 10 has a high withstand voltage. Note that, as shown in FIG. 12, if the corner portion 120c of the gate trench 120 is located outside the electric field relaxation region 130 due to a positional deviation between the gate trench 120 and the electric field relaxation region 130, electric field concentration occurs around the corner portion. On the other hand, in the manufacturing method described above, since the electric field relaxation region 36 and the gate trench 14 are formed using the common mask 50, the positional deviation of the electric field relaxation region 36 with respect to the gate trench 14 (more specifically, the positional deviation of the center C36 of the electric field relaxation region 36 relative to the center C14 of the gate trench 14) can be suppressed. Therefore, it is less likely that the corner portion 14c will protrude outside the electric field relaxation region 36. According to the manufacturing method described above, the electric field concentration near the bottom end of the gate trench 14 can be more reliably suppressed. Furthermore, in the manufacturing method described above, there is almost no positional deviation of the electric field relaxation region 36 with respect to the gate trench 14. Therefore, even if the width W36 of the electric field relaxation region 36 is not so wide, it is possible to suppress the corner portion 14c from protruding outside the electric field relaxation region 36. Since the width W36 of the electric field relaxation region 36 can be made relatively small, the MOSFET 10 can be reduced in size. Further, since the width W36 of the electric field relaxation region 36 can be made relatively small, electrons can flow through a relatively short path as indicated by the arrow 92 in FIG. 9. As such, the on-resistance of MOSFET 10 can be lowered.

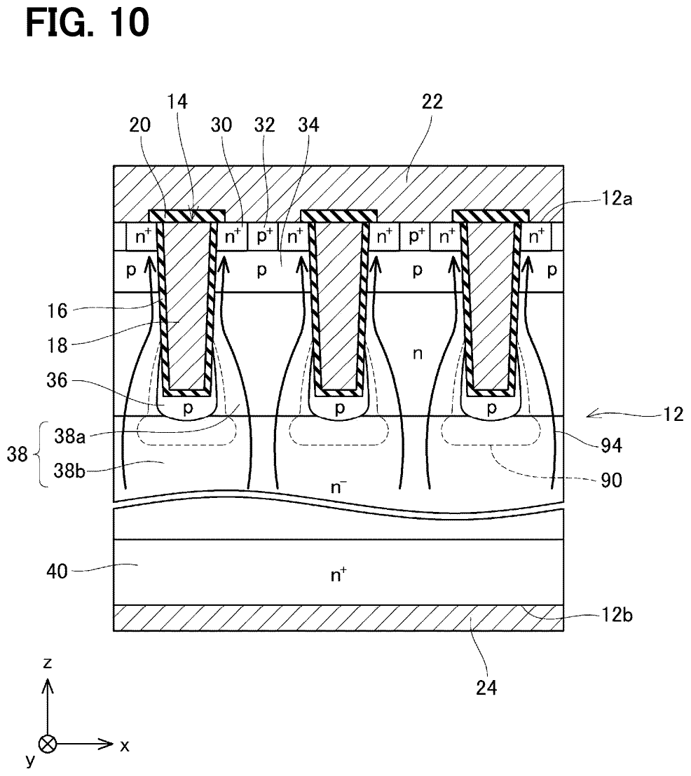

A broken line 90 in FIG. 9 indicates a depletion layer that spreads from the electric field relaxation region 36 to its periphery due to the built-in potential when the MOSFET 10 is on. Further, the arrow 92 in FIG. 9 indicates the path through which electrons flow when the MOSFET 10 is on, as described above. As shown in FIG. 9, when the MOSFET 10 is on, the electrons flow avoiding the depletion layer 90. Since the n-type impurity concentration in the high concentration region 38a adjacent to the electric field relaxation region 36 is relatively high, the range in which the depletion layer 90 expands is narrow. Therefore, the electrons can flow along a relatively short path, as shown by the arrow 92. As such, the on-resistance of MOSFET 10 is low. Further, FIG. 10 shows, as a comparative example, a current path in a MOSFET in which the electric field relaxation region 36 is formed so as to protrude from the high concentration region 38a to the low concentration region 38b. In the case where the electric field relaxation region 36 is in contact with the low concentration region 38b as shown in FIG. 10, when the MOSFET 10 is on, the depletion layer 90 widely spreads from the high concentration region 38a into the low concentration region 38b due to the built-in potential as the low concentration region 38b having the lower n-type impurity concentration. When the depletion layer 90 spreads widely in the low concentration region 38b in this way, the electrons flow in a large detour to avoid the depletion layer 90, as shown by an arrow 94. As a result, the path through which the electrons flow becomes longer, and the on-resistance of the MOSFET increases. For example, in the method of forming the electric field relaxation region in which the p-type impurity is implanted to the bottom of the gate trench shown in FIG. 13 as the relevant technology, the position of the bottom end of the electric field relaxation region is likely to largely vary due to the variation in depth of the gate trench. As a result, when attempting to form the electric field relaxation region 36 in the high concentration region 38a as shown in FIG. 9, the electric field relaxation region 36 may come into contact with the low concentration region 38b as shown in FIG. 10. Therefore, if the field relaxation diffusion region is formed by implanting the p-type impurity to the bottom of the gate trench, the variation in the on-resistance of the MOSFET will increase. On the other hand, in the manufacturing method of the embodiment described above, since the gate trench 14 is formed after the electric field relaxation region 36 is formed, the position of the bottom end of the electric field relaxation region 36 (that is, the distance L36) is not affected by the variation in the depth of the gate trench 14. Therefore, according to the manufacturing method of the embodiment described above, the variation in the position of the bottom end of the electric field relaxation region 36 can be suppressed, and it is possible to suppress the electric field relaxation region 36 from being formed in contact with the low concentration region 38b. Therefore, by manufacturing the MOSFET 10 using the manufacturing method of the embodiment, the variation in the on-resistance of the MOSFET 10 can be suppressed.

In the manufacturing method of the embodiment described above, the electric field relaxation region 36 is formed so as to have the width that increases toward the bottom end, and the gate trench 14 is formed so as to have the width that decreases toward the bottom end. Therefore, at the position of the bottom surface of the gate trench 14, the width W36 of the electric field relaxation region 36 can be made larger than the width W14 of the gate trench 14. As such, the gate trench 14 and the electric field relaxation region 36 can be arranged so that the corner portion 14c of the gate trench 14 is reliably covered with the electric field relaxation region 36. The electric field concentration near the lower end of the gate trench 14 can be more reliably suppressed. In other embodiments, the electric field relaxation region 36 may not be formed to have a wider width toward the bottom end, and the gate trench 14 may not be formed to become narrower toward the bottom end. For example, in a case where the electric field relaxation region 36 is formed so that the width becomes wider toward the bottom end, the gate trench 14 does not need to be formed so that the width becomes narrower toward the bottom end. For example, in a case where the gate trench 14 is formed so that the width becomes narrower toward the bottom end, the electric field relaxation region 36 does not need to be formed so that the width becomes wider toward the bottom end. As long as the corner portion 14c of the gate trench 14 can be covered with the electric field relaxation region 36, the electric field relaxation region 36 and the gate trench 14 may have any shape.

Further, according to the manufacturing method of the embodiment described above, the electric field relaxation region 36 can be formed with high precision, so that the variation in the width W38 in the z direction of the portion where the high concentration region 38a is in contact with the gate insulating film 16 (that is, the portion between the body region 34 and the electric field relaxation region 36) can be suppressed. The width W38 affects a mirror capacitance of the MOSFET 10. According to the manufacturing method of the embodiment described above, since the variation in the width W38 is suppressed, the variation in the mirror capacitance of the MOSFET 10 can be suppressed. In particular, in the manufacturing method of the embodiment described above, the side surface of the gate trench 14 is etched after the gate trench 14 is formed. By etching the side surfaces of the gate trench 14, the width W38 can be ensured widely. By ensuring the wide width W38, the variation in the width W38 is suppressed, and the variation in the mirror capacitance is suppressed more effectively.

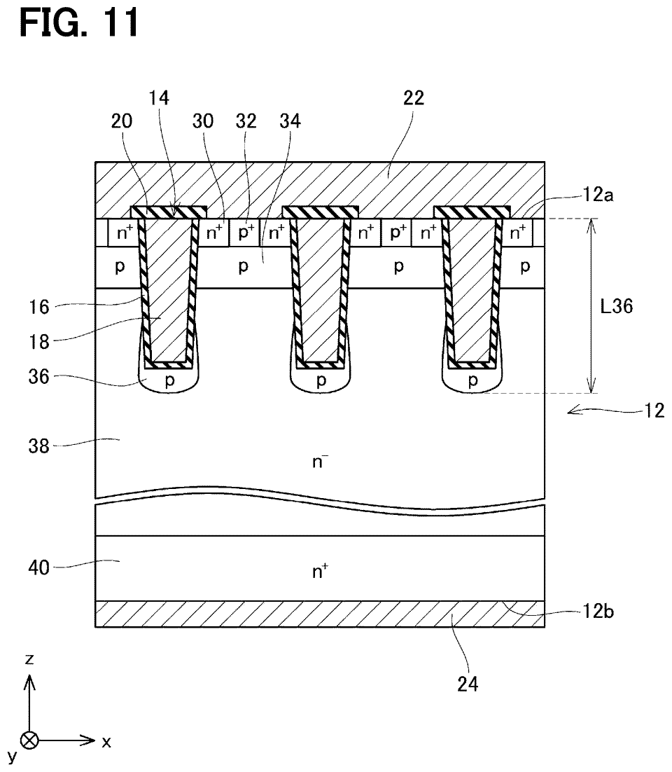

Note that in the embodiment described above, the drift region 38 has the high concentration region 38a and the low concentration region 38b. Alternatively, as shown in FIG. 11, the drift region 38 may be composed of an n-type region of a single concentration. Also in this case, by suppressing the variation in the position of the bottom end of the electric field relaxation region 36 (that is, the distance L36), the variation in the characteristics of the MOSFET can be suppressed.

In the manufacturing method of the embodiment described above, the source regions 30, the contact regions 32, and the body region 34 are formed before forming the electric field relaxation region 36 and the gate trench 14. However, the source regions 30, the contact regions 32, and the body region 34 may be formed by ion implantation or the like, after the electric field relaxation region 36 and the gate trench 14 are formed.

In the embodiments described above, the MOSFET has been described as the example of the switching device. Alternatively, the technology disclosed herein may be applied to other switching devices (for example, insulated gate bipolar transistors (IGBT) or the like).

Although the embodiments have been described in detail above, these are merely examples and do not limit the scope of claims. The techniques described in the claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A method for manufacturing a switching device, the switching device including:
a semiconductor substrate having a gate trench in an upper surface thereof;
a gate electrode disposed in the gate trench and insulated from the semiconductor substrate by a gate insulating film;
an n-type source region in contact with the gate insulating film at a side surface of the gate trench;
a p-type body region in contact with the gate insulating film at the side surface of the gate trench below the source region;
a p-type electric field relaxation region in contact with the gate insulating film at a bottom surface of the gate trench; and
an n-type drift region in contact with the gate insulating film at the side surface of the gate trench below the body region and in contact with a side surface and a bottom surface of the electric field relaxation region,
the method comprising:
forming the source region and the body region in the semiconductor substrate having the drift region;
forming a mask having an opening on the upper surface of the semiconductor substrate having the drift region;
after the forming of the mask, forming the electric field relaxation region in the drift region by implanting a p-type impurity into the semiconductor substrate through the opening;
after the forming of the electric field relaxation region, forming the gate trench by etching the upper surface of the semiconductor substrate within the opening of the mask so that the electric field relaxation region remains below the gate trench; and
after the forming of the gate trench, forming the gate insulating film and the gate electrode.

2. The method according to claim 1, wherein
in the forming of the electric field relaxation region, the electric field relaxation region is formed so that a width of the electric field relaxation region increases toward a bottom of the electric field relaxation region.

3. The method according to claim 2, wherein
in the forming of the gate trench, the gate trench is formed so that a width of the gate trench reduces toward a bottom of the gate trench.

4. The method according to claim 1, further comprising:
etching the side surface of the gate trench, after the forming of the gate trench.

5. The method according to claim 1, wherein
the gate trench is formed so that a width of the bottom surface of the gate trench is smaller than the width of the electric field relaxation region, and
in the forming of the gate trench, the gate trench is formed so that the electric field relaxation region is in contact with a corner portion defined between the bottom surface and the side surface of the gate trench.

6. The method according to claim 1, wherein
the drift region includes a low concentration region and a high concentration region that has an n-type impurity concentration higher than that of the low concentration region and disposed above the low concentration region, and
in the forming of the electric field relaxation region, the electric field relaxation region is formed in the high concentration region such that a bottom end of the electric field relaxation region is located within the high concentration region.

7. A switching device comprising:
a semiconductor substrate having a plurality of gate trenches in an upper surface thereof;
a plurality of gate electrodes disposed in the plurality of gate trenches and insulated from the semiconductor substrate by gate insulating films;
a plurality of n-type source regions in contact with the gate insulating films at side surfaces of the plurality of gate trenches;
a p-type body region in contact with the gate insulating films at the side surfaces of the plurality of gate trenches below the plurality of source regions;
a plurality of p-type electric field relaxation regions in contact with the gate insulating films at bottom surfaces of the plurality of gate trenches; and
an n-type drift region in contact with the gate insulating films at the side surfaces of the plurality of gate trenches below the body region, and in contact with side surfaces and bottom surfaces of the plurality of electric field relaxation regions, wherein
in each of the plurality of gate trenches, a deviation between a center of the gate trench in a width direction and a center of the corresponding electric field relaxation region in the width direction below the corresponding gate trench is 0.1 μm or less, and
among the plurality of electric field relaxation regions, a variation in a distance from the upper surface of the semiconductor substrate to a bottom end of the electric field relaxation region in a thickness direction of the semiconductor substrate is ±2% or less.

8. The switching device according to claim 7, wherein
in each of the plurality of gate trenches, the width of the bottom surface of the gate trench is smaller than the width of the corresponding electric field relaxation region disposed below the gate trench, and
in each of the plurality of gate trenches, the corresponding electric field relaxation region is in contact with each corner portion defined between the bottom surface of the gate trench and the side surface of the gate trench.
